(19) United States
(12) Patent Application Publication
(10) Pub. No.: US 2026/0123543 A1
(43) Pub. Date: Apr. 30, 2026

(54) SEMICONDUCTOR CHIP AND SEMICONDUCTOR PACKAGE STRUCTURE

(71) Applicant: CXMT Corporation, Hefei (CN)

(72) Inventor: Tianqi Fan, Hefei, Anhui (CN)

(73) Assignee: CXMT Corporation, Hefei (CN)

(21) Appl. No.: 19/263,757

(22) Filed: Jul. 9, 2025

Related U.S. Application Data
(63) Continuation of application No. PCT/CN2025/084340, filed on Mar. 24, 2025.

(30) Foreign Application Priority Data
Oct. 22, 2024 (CN) 202411473147.2

(51) Int. Cl. H01L 23/00

(52) U.S. Cl. CPC H10W 90/00; H10W 72/9445; H10W 90/754; H10W 90/792

(57) ABSTRACT

The present disclosure relates to a semiconductor chip and a semiconductor package structure. The semiconductor chip includes: address pads, where the address pads are distributed along the direction perpendicular to the central axis of the semiconductor chip, and the address pads are in mirror symmetry, with the central axis of the semiconductor chip as the center line; and data pads, where the data pads are distributed along the direction perpendicular to the central axis of the semiconductor chip, and the data pads are in mirror symmetry, with the central axis of the semiconductor chip as the center line. The mirror-symmetrical address pads further include a first flip circuit, the first flip circuit being configured to achieve signal interchange between the mirror-symmetrical address pads, and the mirror-symmetrical data pads further include a second flip circuit, the second flip circuit being configured to achieve signal interchange between the mirror-symmetrical data pads.

### CROSS-REFERENCE TO RELATED APPLICATIONS

This application is a continuation of International Patent Application No. PCT/CN2025/084340, filed on Mar. 24, 2025, which claims the benefit of Chinese Patent Application No. 202411473147.2, titled “SEMICONDUCTOR CHIP AND SEMICONDUCTOR PACKAGE STRUCTURE”, filed with the China National Intellectual Property Administration (CNIPA) on Oct. 22, 2024, the disclosures of which are incorporated herein by reference in their entireties.

### TECHNICAL FIELD

The present disclosure relates to the technical field of semiconductors, particularly to a semiconductor chip and a semiconductor package structure.

### BACKGROUND

In the technical field of semiconductors, particularly in semiconductor package design, signal integrity is a critical factor. When a chip and another chip are attached in a mirror-image manner (i.e., the chip and the other chip are bonded in a face-to-face manner) to form a dual memory module (rank), the pads of the two chips need to be connected through a rerouting layer/redistribution layer (RDL) in order to achieve correct transmission of signals. The function of the rerouting layer/redistribution layer (RDL) is to redistribute the signal paths so that signals can be led out from the pads of the chip to the external pins of the package, while also optimizing the signal transmission paths.

However, due to the difference in the positions of the same signal pad between the two chips, the introduction of the rerouting layer/redistribution layer (RDL) increases the length of the signal paths, resulting in differences in the signal trace lengths within the dual memory module (rank). The length difference is particularly critical in a T-shaped topological structure, because the T-shaped topology means that a signal is divided into two paths after reaching a certain point, and if the lengths of the two paths are inconsistent, the difference in the signal reaching time is caused, the signal synchronization and integrity are influenced, and the signal quality is reduced.

It should be noted that the information disclosed in the above background section is only used for enhancement of understanding of the background of the present disclosure, and therefore, may include information that does not constitute the prior art known to those of ordinary skill in the art.

### SUMMARY

The present disclosure provides a semiconductor chip and a semiconductor package structure, capable of improving the signal quality of the semiconductor chip.

Additional features and advantages of the present disclosure will become apparent from the detailed description below, or will be learned in part by practice of the present disclosure.

According to one aspect of the present disclosure, a semiconductor chip is provided. The semiconductor chip includes: address pads, where the address pads are distributed along the direction perpendicular to the central axis of the semiconductor chip, and the address pads are in mirror symmetry, with the central axis of the semiconductor chip as the center line; and
data pads, where the data pads are distributed along the direction perpendicular to the central axis of the semiconductor chip, and the data pads are in mirror symmetry, with the central axis of the semiconductor chip as the center line.

Between the address pads that are mirror-symmetrical to each other, a first flip circuit is further included, and the first flip circuit is configured to be capable of achieving signal interchange between the address pads that are mirror-symmetrical to each other; between the data pads that are mirror-symmetrical to each other, a second flip circuit is further included, and the second flip circuit is configured to be capable of achieving signal interchange between the data pads that are mirror-symmetrical to each other.

According to another aspect of the present disclosure, a semiconductor package structure is provided. The semiconductor package structure includes:
a substrate; and
a plurality of stacked units, where each of the plurality of stacked units is obtained by face-to-face bonding of two of the above semiconductor chips.

The substrate and the plurality of stacked units are bonded by wires, and one end of each of the wires is located at the middle position of the face-to-face bonded semiconductor chips.

It should be understood that both the foregoing general description and the subsequent detailed description are exemplary and explanatory only and are not intended to limit the present disclosure.

### BRIEF DESCRIPTION OF DRAWINGS

The drawings, which are incorporated in and constitute a part of this specification, illustrate embodiments consistent with the present disclosure and, together with the specification, serve to explain the principles of the present disclosure. It is apparent that the drawings in the description below are only for some embodiments of the present disclosure, and for those of ordinary skill in the art, other drawings may be acquired according to the drawings without creative efforts.

FIG. 1 illustrates a cross-sectional view of a semiconductor package structure in the prior art;

FIG. 2 is a top view of the partial pad distribution of a semiconductor chip according to an embodiment of the present disclosure;

FIG. 3 is a schematic diagram of a first flip circuit in a semiconductor chip according to an embodiment of the present disclosure;

FIG. 4 is a schematic diagram of a second flip circuit in a semiconductor chip according to an embodiment of the present disclosure; and

FIG. 5 is a schematic diagram of stacked semiconductor chips according to an embodiment of the present disclosure.

FIG. 6 is a top view of the partial pad distribution of a semiconductor chip according to an embodiment of the present disclosure;

FIG. 7 is a schematic diagram of a third flip circuit in a semiconductor chip according to an embodiment of the present disclosure;

FIG. 8 is a top view of the partial pad distribution on one side of the central axis of a semiconductor chip according to an embodiment of the present disclosure;

FIG. 9 is a top view of the partial pad distribution on the other side of the central axis of a semiconductor chip according to an embodiment of the present disclosure;

FIG. 10 illustrates a schematic structural diagram of a semiconductor package structure according to an embodiment of the present disclosure; and

FIG. 11 illustrates a schematic structural diagram of a semiconductor package structure according to another embodiment of the present disclosure.

### DESCRIPTION OF EMBODIMENTS

To facilitate understanding of the present disclosure, a more comprehensive description of the present disclosure will be provided hereinafter with reference to the relevant drawings. The drawings illustrate the preferred embodiments of the present disclosure. However, the present disclosure can be implemented in many different forms and is not limited to the embodiments described herein. Rather, these embodiments are provided to make the disclosed content more thorough and comprehensive.

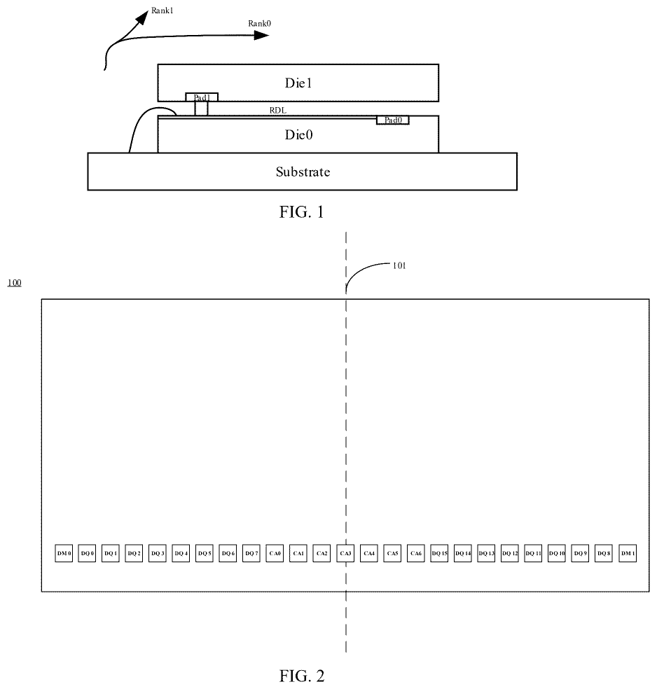

In a semiconductor package design, signal integrity is a critical factor. As shown in FIG. 1, in a semiconductor package structure of the prior art, chip 0 (Die0) and chip 1 (Die 1) are attached in a mirror-image manner (i.e., the two chips are face-to-face) by bonding through micro bumps, and then the two chips are electrically connected to a substrate by wire bonding. When chip 0 (Die0) and chip 1 (Die1) form a dual memory module (rank), i.e., chip 0 (Die0) belongs to rank0, and chip 1 (Die1) belongs to rank1, the pads of the two chips need to be connected through a rerouting layer/redistribution layer (RDL) in order to achieve correct transmission of signals.

However, due to the difference in the positions of the same signal pad between chip 0 (Die0) and chip 1 (Die1)—that is, the same signal pad on chip 0 (Die0) and chip 1 (Die1) corresponds to pad 0 (Pad0) and pad 1 (Pad1), respectively—the introduction of the rerouting layer/redistribution layer (RDL) increases the length of the signal path, resulting in differences in the signal trace lengths within the dual memory module (rank). The length difference is particularly critical in a T-shaped topological structure, because the T-shaped topology means that a signal is divided into two paths after reaching a certain point, and if the lengths of the two paths are inconsistent, the difference in the signal reaching time is caused, the signal synchronization and integrity are influenced, and the signal quality is reduced.

In view of this, the embodiments of the present disclosure provide a semiconductor chip and a semiconductor package structure, in which a novel pad distribution mode for the semiconductor chip has been designed, i.e., address pads and data pads are arranged to be distributed along the direction perpendicular to the central axis of the semiconductor chip, and the address pads and the data pads are respectively in mirror symmetry, with the central axis of the semiconductor chip as the center line. In this way, in the chip package process, a rerouting layer/redistribution layer (RDL) connected to the pads is not required to be introduced, thereby reducing the difference in the signal trace lengths within the dual memory module (rank), and finally improving the signal synchronization and integrity, as well as signal quality.

To make the objectives, technical solutions, and advantages of the embodiments of the present disclosure clearer, the technical solutions in the embodiments of the present disclosure are clearly and completely described below with reference to the drawings in the embodiments of the present disclosure, and it is obvious that the described embodiments are part of the embodiments of the present disclosure, but not all of them. Based on the embodiments of the present disclosure, all other embodiments obtained by those of ordinary skill in the art without creative efforts shall fall within the protection scope of the present disclosure.

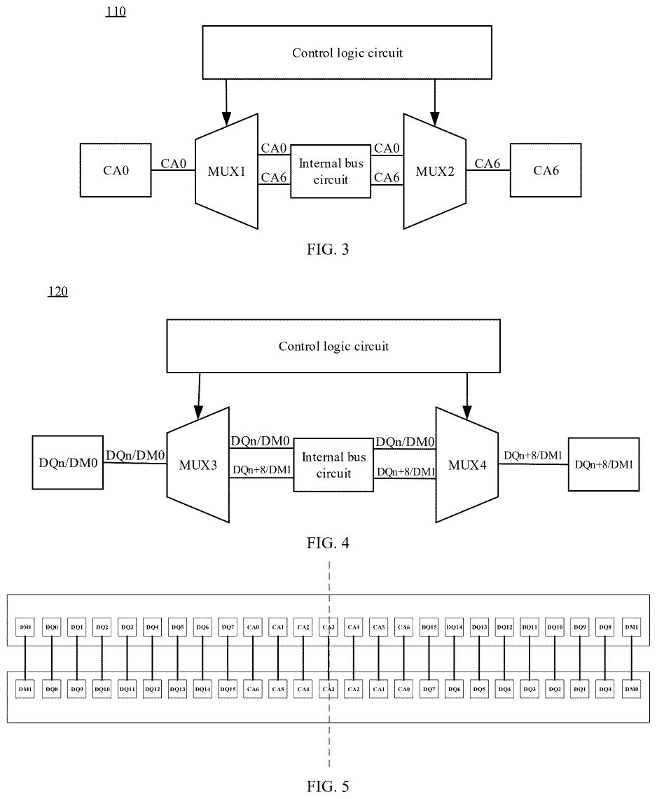

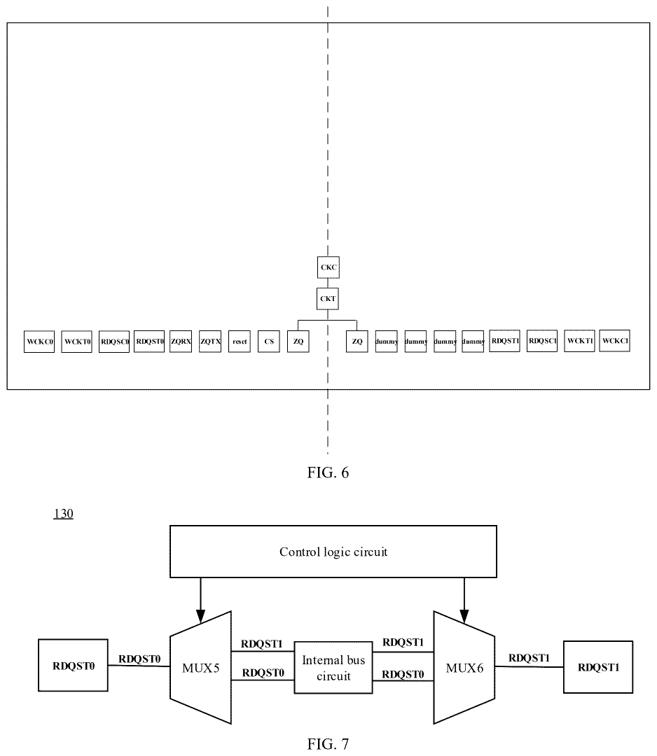

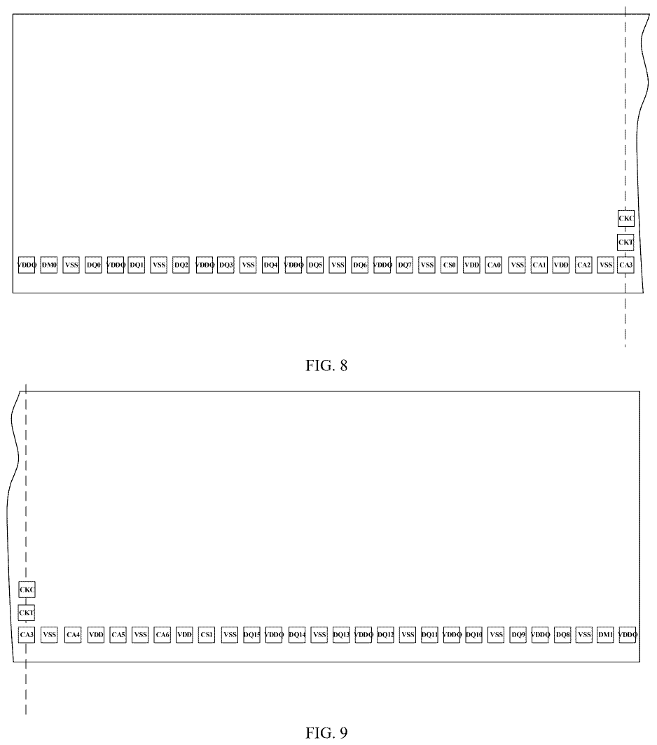

FIG. 2 is a top view of the partial pad distribution of a semiconductor chip according to an embodiment of the present disclosure; FIG. 3 is a schematic diagram of a first flip circuit in a semiconductor chip according to an embodiment of the present disclosure; FIG. 4 is a schematic diagram of a second flip circuit in a semiconductor chip according to an embodiment of the present disclosure; and FIG. 5 is a schematic diagram of stacked semiconductor chips according to an embodiment of the present disclosure. FIG. 6 is a top view of the partial pad distribution of a semiconductor chip according to an embodiment of the present disclosure; FIG. 7 is a schematic diagram of a third flip circuit in a semiconductor chip according to an embodiment of the present disclosure; FIG. 8 is a top view of the partial pad distribution on one side of the central axis of a semiconductor chip according to an embodiment of the present disclosure; and FIG. 9 is a top view of the partial pad distribution on the other side of the central axis of a semiconductor chip according to an embodiment of the present disclosure.

Referring to FIG. 2, in one embodiment, a semiconductor structure 100 includes:
address pads, where the address pads are distributed along the direction perpendicular to the central axis 101 of the semiconductor chip 100, and the address pads are in mirror symmetry, with the central axis 101 of the semiconductor chip 100 as the center line; and
data pads, where the data pads are distributed along the direction perpendicular to the central axis 101 of the semiconductor chip 100, and the data pads are in mirror symmetry, with the central axis 101 of the semiconductor chip 100 as the center line.

Between the address pads that are mirror-symmetrical to each other, a first flip circuit is further included. The first flip circuit is configured to be capable of achieving signal interchange between the mirror-symmetrical address pads. Between the data pads that are mirror-symmetrical to each other, a second flip circuit is further included. The second flip circuit is configured to be capable of achieving signal interchange between the mirror-symmetrical data pads.

Referring to FIGS. 2 to 5, the above semiconductor chip 100 is described in detail.

The address pads are physical contact points on the semiconductor chip 100 for receiving address signals. These pads are part of a chip package. The pads are connected to internal circuits of the chip through internal wiring of the semiconductor chip 100, and are configured to transmit address information between an external device (such as a CPU or a controller) and the semiconductor chip 100. In a DRAM, there are typically a plurality of address pads, such as CA0 to CA6, which jointly form an address bus for transmitting column addresses (column address) and row addresses (row address) information to achieve precise addressing of memory cells. In this embodiment, the address pads (CA0 to CA6) are distributed along the direction perpendicular to the central axis 101 of the semiconductor chip 100, i.e., the address pads (CA0 to CA6) are arranged along the perpendicular direction of the central axis 101 of the semiconductor chip 100. Moreover, the address pads (CA0 to CA6) are in mirror symmetry, with the central axis 101 of the semiconductor chip 100 as the center line. The central axis 101 of the semiconductor chip 100 may be the central axis of the long side of the semiconductor chip 100 or the central axis of the short side of the semiconductor chip 100. The mirror-symmetrical layout can ensure that the trace lengths of all address signals are approximately equal, thereby reducing the signal delay difference and improving signal synchronization.

The data pads refer to physical contact points on the semiconductor chip 100 for controlling, receiving, and transmitting data signals. The data pads are connected to the internal circuits of the semiconductor chip 100 through the internal wiring of the semiconductor chip 100, and are configured to transmit data information between an external device (such as a CPU, a controller, or other chips) and the semiconductor chip 100. In this embodiment, the data pads include data signal pads (DQ0 to DQ15) and data mask pads (DM0 to DM1). The data mask pads (DM0 to DM1) are connected to the internal circuits of the chip through the internal wiring of the chip and configured to receive data mask signals. When the data mask signals are activated, the data mask signals indicate which data bits should be ignored or modified. For example, on a 16-bit data bus, if DM0 and DM1 correspond to data bits of DQ0 to DQ7 and DQ8 to DQ15, respectively, then the data bits of DQ0 to DQ7 or DQ8 to DQ15 can be selectively ignored or modified by activating DM0 or DM1, respectively. In this embodiment, the data pads (DQ0 to DQ15/DM0 to DM1) are distributed along the direction perpendicular to the central axis 101 of the semiconductor chip 100, i.e., the data pads (DQ0 to DQ15/DM0 to DM1) are arranged along the perpendicular direction of the central axis 101 of the semiconductor chip 100. Moreover, the data pads (DQ0 to DQ15/DM0 to DM1) are in mirror symmetry, with the central axis 101 of the semiconductor chip 100 as the centerline. The central axis 101 of the semiconductor chip 100 may be the central axis of the long side of the semiconductor chip 100 or the central axis of the short side of the semiconductor chip 100. The mirror-symmetrical layout can ensure that the trace lengths of all data signals and data mask signals are approximately equal, thereby reducing the signal delay difference and improving signal synchronization.

By arranging the address pads and the data pads to be distributed along the direction perpendicular to the central axis of the semiconductor chip, and arranging the address pads and the data pads to be respectively in mirror symmetry, with the central axis of the semiconductor chip as the center line, the mirror-symmetrical signal layout is beneficial to reducing the reflection and crosstalk of signals in the transmission process, improving the signal integrity, ensuring the signal definition and stability, reducing the mutual interference between signals, and improving the signal reliability. Meanwhile, the design of the redistribution layer (RDL) can be simplified, the complexity and cost of the packaging process are lowered, and the routing and optimization of the signals are facilitated. Additionally, the mirror-symmetrical signal layout is beneficial to improving the packaging reliability, reducing signal errors and data transmission problems, and ensuring the data accuracy and integrity. Furthermore, the mirror-symmetrical signal layout helps to optimize thermal management, as heat can be more evenly distributed, thus avoiding local overheating and improving the thermal performance of the package.

The semiconductor chip 100 in this embodiment further includes a first flip circuit 110. The first flip circuit 110 is arranged between the mirror-symmetrical address pads, and the first flip circuit is configured to be capable of achieving signal interchange between the mirror-symmetrical address pads. Referring to FIG. 3, the first flip circuit 110 is capable of achieving signal interchange between address pad CA0 and address pad CA6. Similarly, the first flip circuit is also capable of achieving signal interchange between address pad CA0 and address pad CA5, as well as between address pad CA1 and address pad CA4. The first flip circuit 110 includes a plurality of multiplexers (MUX1 and MUX2), an internal bus circuit, and a control logic circuit. The plurality of multiplexers are configured to select one address signal from a plurality of address signals to input to the address pad; the internal bus circuit is configured to input a plurality of address signals to the plurality of multiplexers; the control logic circuit is configured to be responsible for generating a control signal for controlling the switching behavior of the multiplexers. In this way, the first flip circuit 110 can reroute the address signal onto its mirror-symmetrical pad to achieve a shorter signal path, thereby improving signal quality.

The semiconductor chip 100 in this embodiment further includes a second flip circuit 120. The second flip circuit 120 is arranged between the mirror-symmetrical data pads, and the second flip circuit is configured to be capable of achieving signal interchange between the mirror-symmetrical data pads. Referring to FIG. 4, the second flip circuit 120 is capable of achieving signal interchange between data mask pad DM0 and data mask pad DM1. Similarly, the second flip circuit is also capable of achieving signal interchange between data pad DQn and data pad DQn+8. The second flip circuit 120 includes a plurality of multiplexers (MUX3 and MUX4), an internal bus circuit, and a control logic circuit. The plurality of multiplexers are configured to select one data signal from a plurality of data signals to input to the data pad; the internal bus circuit is configured to input a plurality of data signals to the plurality of multiplexers; the control logic circuit is configured to be responsible for generating a control signal for controlling the switching behavior of the multiplexers. In this way, the second flip circuit 120 can reroute the data signal onto its mirror-symmetrical pad to achieve a shorter signal path, thereby improving signal quality.

Referring to FIG. 4, when chip 0 (Die0) and chip 1 (Die1) are attached in a mirror-image manner (i.e., the two chips are face-to-face) by bonding, one of the chips may be configured to perform a signal flipping operation. In this way, the positions of the same signal pads on chip 0 (Die0) and chip 1 (Die1) are the same. For example, the signal of the pad DM1 on chip 0 (Die0) is the same as the signal of the pad DM0 on chip 1 (Die1), the signals of the pads DQ0 to DQ7 on chip 0 (Die0) are the same as the signals of the pads DQ8 to DQ15 on chip 1 (Die1), the signals of the address pads (CA0, CA1, CA2, CA4, CA5, CA6) on chip 0 (Die0) are the same as the signals of the address pads (CA6, CA5, CA4, CA3, CA2, CA1) on chip 1 (Die1), respectively. In this way, by performing the signal flipping operation, the positions of the same signal pads on the two chips can be aligned. This alignment optimizes the signal trace lengths and reduces the signal trace length differences between the two chips within the dual memory module (rank), thereby improving signal integrity and system performance.

In one embodiment, one of the address pads is located on the central axis 101 of the semiconductor chip 100. Referring to FIG. 2, one of the address pads, i.e., the pad CA3, is located on the central axis 101 of the semiconductor chip 100. In this way, other address pads may be in mirror symmetry, with the central axis 101 of the semiconductor chip 100 as the centerline, thereby providing more flexibility for the layout of the other pads, and facilitating the optimization of signal paths and the improvement of signal integrity in the package design.

In one embodiment, the data pads include low-bit data pads and high-bit data pads, where the low-bit data pads are sequentially in mirror symmetry to the high-bit data pads, with the central axis of the semiconductor chip as the center line. The low-bit data pads include a low-bit data mask pad DM0 and low-bit data signal pads DQ0 to DQ7, and the high-bit data pads include a high-bit data mask pad DM1 and high-bit data signal pads DQ8 to DQ15. The low-bit data mask pad DM0 and the high-bit data mask pad DM1 are in mirror symmetry, with the central axis of the semiconductor chip as the center line. The low-bit data signal pads DQ0 to DQ7 are sequentially in mirror symmetry to the high-bit data signal pads DQ8 to DQ15, with the central axis of the semiconductor chip as the center line, that is, DQ0 and DQ8, DQ1 and DQ9, DQ2 and DQ10, DQ3 and DQ11, DQ4 and DQ12, DQ5 and DQ13, DQ6 and DQ14, DQ7 and DQ15 are respectively in mirror symmetry, with the central axis of the semiconductor chip as the center line. In addition, the low-bit data pads are distributed on the same side of the central axis of the semiconductor chip, namely on the left side or the right side of the central axis of the semiconductor chip; the high-bit data pads are distributed on the same side of the central axis of the semiconductor chip, namely on the left side or the right side of the central axis of the semiconductor chip. In this way, the signal routing can be simplified and the crossing of signal lines can be reduced, thereby optimizing signal paths, reducing signal delay and reflection, and improving signal integrity.

In one embodiment, referring to FIG. 6, the semiconductor chip further includes control command pads. The control command pads are distributed along the direction perpendicular to the central axis of the semiconductor chip. That is, the control command pads are arranged along the perpendicular direction of the central axis 101 of the semiconductor chip 100, so that the trace lengths of all the control command signals can be kept consistent as much as possible, thereby reducing the signal delay difference and improving the signal synchronization.

In one embodiment, referring to FIG. 6, the address pads, the data pads, and the control command pads are distributed near one side edge of the semiconductor chip. That is, the address pads, the data pads, and the control command pads are not distributed on four or two side edges of the semiconductor chip, nor distributed in the center of the semiconductor chip, but distributed near one side edge of the semiconductor chip. In this way, the package design can be simplified and the complexity of the redistribution layer (RDL) can be reduced, thus lowering the package cost while facilitating the signal routing and optimization.

In one embodiment, referring to FIG. 6, the control command pads include a plurality of calibration pads ZQ. The plurality of calibration pads are in mirror symmetry, with the central axis of the semiconductor chip as the center line, and the plurality of calibration pads are electrically connected to each other. In the design of semiconductor memory, especially dynamic random access memory (DRAM), the calibration pad ZQ is a key component for calibrating the impedance of the data bus, thus ensuring the integrity and stability of the data signal. The plurality of calibration pads ZQ are electrically connected to each other, which can ensure the uniformity of impedance throughout the chip or package. In high-speed data transmission, impedance mismatching may cause signal reflection and signal quality reduction, and the electrically interconnected calibration pads ZQ can reduce such mismatching and improve the integrity of signals. Meanwhile, the electrically interconnected calibration pads ZQ can ensure that signal calibration is uniformly carried out in different areas (both sides of the central axis of the semiconductor chip) of the chip, thereby avoiding local signal quality discrepancies and improving the signal quality of the whole system.

In one embodiment, referring to FIG. 6, the control command pads include clock signal pads. The clock signal pads are located on the central axis of the semiconductor chip and distributed side-by-side with the address pads. The clock signal pads are physical contact points configured to receive and transmit clock signals. These signals are critical for the synchronization operation of the internal circuits of the chip. The clock signal pads include a CKC signal pad and a CKT signal pad, and the CKC signal pad is a common clock signal pad configured to receive a primary clock signal. The CKT signal pad is configured for clock training or clock data recovery functions. Arranging the clock signal pads on the central axis is beneficial to achieving the symmetry of signal paths, which means that signals propagating from the clock pads to the edges of the chip travel approximately equal distances. This is beneficial to reducing the signal delay difference and improving the signal synchronization. Clock signals are critical synchronization signals in the chip, and the layout of the clock signals has a direct influence on signal synchronization and stability. Distributing the clock signal pads and the address pads side-by-side can ensure the coordination between the clock signals and the address signals, reduce mutual influence among the signals, and improve signal quality.

In one embodiment, referring to FIG. 6, the control command pads include a chip select signal pad (CS), a reset signal pad (reset), a calibration signal transmission pad (ZQTX), and a calibration signal reception pad (ZQRX). The semiconductor chip further includes a plurality of dummy pads (dummy). The plurality of dummy pads are respectively in mirror symmetry to the chip select signal pad, the reset signal pad, the calibration signal transmission pad, and the calibration signal reception pad, with the central axis of the semiconductor chip as the center line. The chip select signal is used to select a specific chip or a memory module. When a CS signal is activated, it indicates that the chip is selected and can receive and respond to external commands and data. The reset signal is used to restore the chip or the system to an initial state, typically when the system is started or an error is encountered. The ZQTX and the ZQRX are configured for signal calibration, particularly in high-speed data transmission, and configured to adjust signal timing, amplitude, and impedance to optimize signal quality. The ZQTX is configured to transmit the calibration signal, while the ZQRX is configured to receive the calibration signal. The calibration process can ensure the impedance matching of the data bus, reduce signal reflection, and improve signal integrity. By arranging the dummy pads in mirror symmetry to the above control command pads, when a chip and another chip are attached in a mirror-image manner (i.e., the two chips are face-to-face) by bonding, it can be ensured that the control command pads of one chip are bonded with the dummy pads of the other chip. In this way, the balanced distribution of signals can be achieved and the differences in the signal path lengths can be reduced, thereby improving the signal synchronization and integrity.

In one embodiment, referring to FIG. 6, the plurality of dummy pads are located on the same side of the central axis of the semiconductor chip. Distributing the dummy pads on one side of the central axis in a centralized manner can simplify signal routing and reduce the crossing of signal lines, thereby optimizing signal paths, reducing signal delay and reflection, and improving signal integrity.

In one embodiment, referring to FIG. 6, the control command pads mirror-symmetrical to the dummy pads are electrically isolated from the dummy pads. Compared with the plurality of calibration pads that are electrically connected to each other, the control command pads mirror-symmetrical to the dummy pads need to be electrically isolated from the dummy pads. In this way, the signal crosstalk between the control command pads mirror-symmetrical to the dummy pads and the dummy pads can be reduced, ensuring the signal definition and stability and improving the signal quality.

In one embodiment, referring to FIG. 6, the control command pads include write clock signal pads (WCKC0, WCKC1, WCKT0, WCKT1) and read data strobe signal pads (RDQSC0, RDQSC1, RDQST0, RDQST1). The WCK signals are used to synchronize data write operations, ensuring that the data is written to the memory cells at the correct time points. The RDQS signals are used to synchronize data read operations, ensuring that the data is read out at the correct time points. The write clock signal pads are in mirror symmetry, with the central axis of the semiconductor chip as the center line. That is, the write clock signal pads WCKC0 and WCKC1 are in mirror symmetry, with the central axis of the semiconductor chip as the center line, and the write clock signal pads WCKT0 and WCKT1 are in mirror symmetry, with the central axis of the semiconductor chip as the center line. The read data strobe signal pads are in mirror symmetry, with the central axis of the semiconductor chip as the center line. That is, the read data strobe signal pads RDQSC0 and RDQSC1 are in mirror symmetry, with the central axis of the semiconductor chip as the center line, and the read data strobe signal pads RDQST0 and RDQST1 are in mirror symmetry, with the central axis of the semiconductor chip as the center line. By distributing the write clock signal pads (WCKC0, WCKC1, WCKT0, WCKT1) and the read data strobe signal pads (RDQSC0, RDQSC1, RDQST0, RDQST1) respectively in mirror symmetry, with the central axis as the center line, the following advantages can be achieved: It is ensured that the trace lengths of the signals are approximately equal, which reduces the signal delay difference and improves the signal synchronization. The symmetrical signal layout helps to reduce the signal reflection and crosstalk in the transmission process and improve the signal definition and stability.

In one embodiment, the semiconductor chip 100 further includes a third flip circuit. The third flip circuit is arranged between the mirror-symmetrical write clock signal pads or read data strobe signal pads, and the third flip circuit is configured to be capable of achieving signal interchange between the mirror-symmetrical write clock signal pads or read data strobe signal pads. As an example, referring to FIG. 7, the third flip circuit 130 is capable of achieving signal interchange between the read data strobe signal pads RDQST0 and RDQST1; the third flip circuit 130 includes a plurality of multiplexers (MUX5 and MUX6), an internal bus circuit, and a control logic circuit. The plurality of multiplexers are configured to select one read data strobe signal from a plurality of data signals to input to the data pads; the internal bus circuit is configured to input a plurality of read data strobe signals to the plurality of multiplexers; the control logic circuit is configured to be responsible for generating a control signal for controlling the switching behavior of the multiplexers. In this way, the third flip circuit 130 can reroute the data signal onto its mirror-symmetrical pad to achieve a shorter signal path, thereby improving signal quality. Likewise, a similar flip circuit also exists between the write clock signal pads WCKC0 and WCKC1, between the write clock signal pads WCKT0 and WCKT1, and between the read data strobe signal pads RDQSC0 and RDQSC1, and details are not described here again.

In one embodiment, referring to FIGS. 8 and 9, the semiconductor chip further includes a plurality of power supply pads. These power supply pads are configured to provide stable power supply voltage to different parts of the chip. VSS generally refers to the grounding voltage of the circuit, namely, the “OV” reference point in the circuit. In a DRAM chip, VSS is a power supply ground pad for providing a ground connection for the circuit, ensuring stable operations of internal circuits of the chip. VDDQ is the power supply voltage dedicated to data lines (DQ), and VDDQ provides the operating voltage for the data input/output parts of the DRAM. The VDDQ voltage is typically slightly lower than the core voltage (VDD) to reduce power consumption and improve data transmission stability. VDD is the core power supply voltage of the chip and provides the operating voltage for most of the circuits of the chip. In a DRAM chip, VDD is the primary power supply voltage for driving internal logic circuits and memory cells of the chip. The power supply pads with the same function are in mirror symmetry, with the central axis of the semiconductor chip as the center line. That is, the ground pads VSS are in mirror symmetry, with the central axis of the semiconductor chip as the center line, the power supply pads VDDQ for data lines are in mirror symmetry, with the central axis of the semiconductor chip as the center line, and the power supply pads VDD for the chip core are in mirror symmetry, with the central axis of the semiconductor chip as the center line. By distributing the power supply pads with the same function in mirror symmetry with the central axis of the semiconductor chip as the center line, the balanced distribution of the power supply lines can be achieved, and the difference in the power supply lines can be reduced, thereby improving the power supply stability and integrity, and optimizing the power supply quality and package performance.

In one embodiment, referring to FIGS. 8 and 9, on both sides of the data pads or the address pads are power supply pads with different functions. That is, on both sides of the data pads are a ground pad VSS and a power supply pad VDDQ for data lines; on both sides of the address pads are a ground pad VSS and a power supply pad VDD for the chip core. The power supply pads of different functions (such as the VDDQ and the VSS or the VDD and the VSS) are distributed on both sides of the data pads or the address pads, so that stable power supply can be ensured, voltage drop and IR drop on power supply lines can be reduced, and stability of the power supply can be improved. This is critical for high-speed data transmission and signal integrity.

On the basis of the above embodiments, the embodiments of the present disclosure further provide a semiconductor package structure. The semiconductor device will be described in detail below.

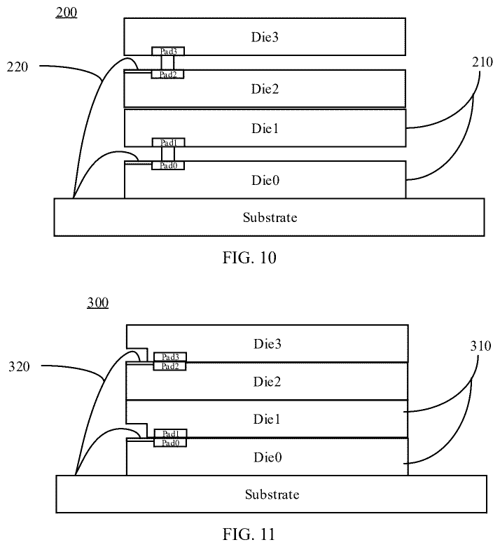

FIG. 10 illustrates a schematic structural diagram of a semiconductor package structure according to an embodiment of the present disclosure.

FIG. 11 illustrates a schematic structural diagram of a semiconductor package structure according to another embodiment of the present disclosure.

Referring to FIG. 10, in one embodiment, a semiconductor package structure 200 is provided. The semiconductor package structure includes:
a substrate (substrate); and
a plurality of stacked units 210, where each stacked unit 210 is obtained by face-to-face bonding of two semiconductor chips (Die0 and Die1, or Die2 and Die3).

The substrate (substrate) and the plurality of stacked units 210 are bonded by wires 220, and one end of each wire is located at the middle position of the face-to-face bonded semiconductor chips (Die0 and Die 1, or Die2 and Die3).

Referring to FIG. 10, the substrate may be a printed circuit board (PCB), a ceramic substrate, an organic substrate, or a special package substrate (package substrate). Chip 0 (Die0) and chip 1 (Die1), as well as chip 2 (Die2) and chip 3 (Die3), are bonded by micro bump bonding in a face-to-face manner, namely, attached in a mirror-image manner. Different stacked units 210 are attached by an adhesive, such as NCF. The wires 220 are metal lines configured to connect the chips and the substrate, and are typically made of gold, copper, or aluminum. In this embodiment, the wires 220 are configured to connect the substrate and the chips in the stacked units. One end of each wire is located at the middle position of the face-to-face bonded semiconductor chips (Die0 and Die1, or Die2 and Die3), which means that the wire may be connected through a bonding region or a gap between the chips to achieve electrical connection between the chips and the substrate. In this way, the height of the semiconductor package structure can be reduced, lowering the complexity and cost of the package while providing sufficient electrical performance and reliability.

Referring to FIG. 11, in another embodiment, a semiconductor package structure 300 is provided. The semiconductor package structure includes:
a substrate (substrate); and
a plurality of stacked units 310, where each stacked unit 310 is obtained by face-to-face bonding of two above semiconductor chips (Die0 and Die1, or Die2 and Die3).

The substrate (substrate) and the plurality of stacked units 310 are bonded by wires 320, and one end of each wire is located at the middle position of the face-to-face bonded semiconductor chips (Die0 and Die 1, or Die2 and Die3).

Referring to FIG. 11, chip 0 (Die0) and chip 1 (Die1), as well as chip 2 (Die2) and chip 3 (Die3), are directly bonded by methods such as hybrid bonding in a face-to-face manner, namely, attached in a mirror-image manner. In this way, in order for one end of each wire to be located at the middle position of the face-to-face bonded semiconductor chips (Die0 and Die1, or Die2 and Die3), the upper chip (Die1, or Die3) of the stacked unit 310 needs to be subjected to a notching process to accommodate the wire contact points; meanwhile, the notching process helps optimize thermal management and avoid local overheating, which is especially important for high power consumption chips. Different stacked units 210 are attached by an adhesive, such as NCF. In this embodiment, the wires 320 are configured to connect the substrate and the chips in the stacked units. This means that the wire may be connected through a bonding region or a gap between the chips to achieve an electrical connection between the chips and the substrate. In this way, the height of the semiconductor package structure can be reduced, lowering the complexity and cost of the package while providing sufficient electrical performance and reliability.

In one embodiment, the two semiconductor chips in each stacked unit are in different memory modules. Referring to FIG. 10, chip 0 (Die0) may be in a memory module 0 (rank0), and chip 1 (Die1) may be in a memory module 1 (rank1). When chip 0 (Die0) and chip 1 (Die1), as well as chip 2 (Die2) and chip 3 (Die3), belong to different memory modules respectively, they may operate through independent control signals and data paths, which means that two modules can be read and written simultaneously, thereby improving the overall memory performance.

In the description of the present disclosure, it should be understood that orientations or positional relationships indicated by terms “center”, “longitudinal”, “transverse”, “length”, “width”, “thickness”, “upper”, “lower”, “front”, “rear”, “left”, “right”, “perpendicular”, “horizontal”, “top”, “bottom”, “inner”, “outer”, and the like are based on the orientations or positional relationships shown in the drawings, and are used for the convenience of description of the present disclosure only and do not indicate or imply that the device or element referred to must have a particular orientation or be constructed and operated in a particular orientation, and therefore, should not be construed as limitations on the present disclosure.

In the description of the present disclosure, it should be understood that the terms “comprise”, “include”, “have”, and any variations thereof used herein are intended to cover non-exclusive inclusions. For example, a process, method, system, product, or device including a series of steps or units is not necessarily limited to those steps or units explicitly listed, but may include other steps or units not explicitly listed or inherent to the process, method, product, or device.

Unless expressly stated and limited otherwise, the terms “mount”, “link”, “connect”, “fix”, and the like should be understood broadly. For example, it can be a fixed connection, a detachable connection, or integration; it can be directly connected or indirectly connected through an intermediate medium and it can enable the internal connection of two elements or the interaction relationship between two elements. For those of ordinary skill in the art, the specific meanings of the above terms in the present disclosure can be understood according to specific circumstances. Furthermore, the terms “first”, “second”, and the like are only used for the purpose of description and should not be construed as indicating or implying relative importance or implicitly indicating the quantity of the indicated technical features.

Finally, it should be noted that the above embodiments are merely used to illustrate the technical solutions of the present disclosure without limiting the same. Although the present disclosure has been described in detail with reference to the foregoing embodiments, those of ordinary skill in the art should understand that the technical solutions described in the foregoing embodiments may still be modified, or some or all of the technical features may be equivalently replaced. These modifications or replacements do not cause the essence of corresponding technical solutions to depart from the scope of the technical solutions of the embodiments of the present disclosure.

What is claimed is:

1. A semiconductor chip,
comprising:
address pads, wherein the address pads are distributed along a direction perpendicular to a central axis of the semiconductor chip, and the address pads are in mirror symmetry, with the central axis of the semiconductor chip as a center line; and
data pads, wherein the data pads are distributed along the direction perpendicular to the central axis of the semiconductor chip, and the data pads are in mirror symmetry, with the central axis of the semiconductor chip as the center line,
wherein between the address pads that are mirror-symmetrical to each other, a first flip circuit is further comprised, and the first flip circuit is configured to be capable of achieving signal interchange between the address pads that are mirror-symmetrical to each other; between the data pads that are mirror-symmetrical to each other, a second flip circuit is further comprised, and the second flip circuit is configured to be capable of achieving signal interchange between the data pads that are mirror-symmetrical to each other.

2. The semiconductor chip according to claim 1, wherein one of the address pads is located on the central axis of the semiconductor chip.

3. The semiconductor chip according to claim 1, wherein the data pads comprise low-bit data pads and high-bit data pads, wherein the low-bit data pads are sequentially in mirror symmetry to the high-bit data pads, with the central axis of the semiconductor chip as the center line.

4. The semiconductor chip according to claim 1, further comprising control command pads, wherein the control command pads are distributed along the direction perpendicular to the central axis of the semiconductor chip.

5. The semiconductor chip according to claim 4, wherein the address pads, the data pads, and the control command pads are distributed near one side edge of the semiconductor chip.

6. The semiconductor chip according to claim 4, wherein the control command pads comprise a plurality of calibration pads, wherein the plurality of calibration pads are in mirror symmetry, with the central axis of the semiconductor chip as the center line, and the plurality of calibration pads are electrically connected to each other.

7. The semiconductor chip according to claim 4, wherein the control command pads comprise clock signal pads, wherein the clock signal pads are located on the central axis of the semiconductor chip and distributed side-by-side with the address pads.

8. The semiconductor chip according to claim 4, wherein the control command pads comprise a chip select signal pad, a reset signal pad, a calibration signal transmission pad, and a calibration signal reception pad, and the semiconductor chip further comprises a plurality of dummy pads, wherein the plurality of dummy pads are respectively in mirror symmetry to the chip select signal pad, the reset signal pad, the calibration signal transmission pad, and the calibration signal reception pad, with the central axis of the semiconductor chip as the center line.

9. The semiconductor chip according to claim 8, wherein the plurality of dummy pads are located on a same side of the central axis of the semiconductor chip.

10. The semiconductor chip according to claim 8, wherein the control command pads mirror-symmetrical to the dummy pads are electrically isolated from the dummy pads.

11. The semiconductor chip according to claim 4, wherein the control command pads comprise write clock signal pads and read data strobe signal pads, wherein the write clock signal pads are in mirror symmetry, with the central axis of the semiconductor chip as the center line, and the read data strobe signal pads are in mirror symmetry, with the central axis of the semiconductor chip as the center line.

12. The semiconductor chip according to claim 1, further comprising a plurality of power supply pads, wherein the power supply pads with a same function are in mirror symmetry, with the central axis of the semiconductor chip as the center line.

13. The semiconductor chip according to claim 12, wherein on both sides of the data pads or the address pads are the power supply pads with different functions.

14. A semiconductor package structure, comprising:
a substrate; and
a plurality of stacked units, wherein each of the plurality of stacked units is obtained by face-to-face bonding of two of the semiconductor chips according to claim 1,
wherein the substrate and the plurality of stacked units are bonded by wires, and one end of each of the wires is located at a middle position of face-to-face bonded semiconductor chips.

15. The semiconductor package structure according to claim 14, wherein the two semiconductor chips in each of the plurality of stacked units are in different memory modules.
